(19) United States
(12) Patent Application Publication
(10) Pub. No.: US 2026/0303067 A1
(43) Pub. Date: Oct. 1, 2026

(54) TRANSITION MATERIAL-BASED NON-BLOCKING MULTIPLE STATE, MULTIPORT RADIO FREQUENCY SWITCH

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/091,575

(22) Filed: Mar. 26, 2025

(51) Int. Cl. H03K 3/011; H03K 17/56

(52) U.S. Cl. CPC H03K 3/011; H03K 17/56

(57) ABSTRACT

The technology described herein is directed towards a phase change material-based (e.g., metal-insulator transition material such as vanadium dioxide) radio frequency (RF) multiport switch device. In various implementations, the multiport switch has five, six or ten phase change material-based switches configured between the device's ports, in which the phase change material switches are controlled to be in either conductive or nonconductive states, thereby respectively coupling or decoupling any port to any other port, e.g., in three different operational states. A controller can selectively output the voltage to heat the material in the respective junctions of respective switches to independently determine their respective conductive or nonconductive states as needed for a specified operational state. In one implementation, the switch design is symmetrical. The example vanadium dioxide material switch described herein provides high switching speeds, low insertion loss, good isolation and is relatively straightforward to fabricate.

### RELATED APPLICATION

The subject patent application is related to U.S. patent application Ser. No. 19/085,912, filed Mar. 20, 2025, entitled “METAL-INSULATOR TRANSITION MATERIAL-BASED MULTIPORT RADIO FREQUENCY SWITCH” (docket no. 141549.01/DELLP1478US, the entireties of which patent application is hereby incorporated by reference herein.

### BACKGROUND

Radio frequency (RF) switches control the routing of RF signals in communication systems, and are used for tasks like antenna selection and signal path switching. Common types of RF switches include PIN diodes, FET (field effect transistor)/GaN (Gallium Nitride) switches, and MEMS (micro-electromechanical systems) switches, each with unique characteristics in terms of speed, power consumption, and performance.

RF switches are used in devices such as mobile phones, base stations, and phased array antennas for tasks like signal routing, antenna switching, and phase shifting.

### BRIEF DESCRIPTION OF THE DRAWINGS

The technology described herein is illustrated by way of example and not limited to the accompanying figures in which like reference numerals indicate similar elements and in which:

FIGS. 1 and 2 are a top view representation and a zoomed-in view representation, respectively, showing an example switch layout of a multiport (e.g., four port) radio frequency (RF) switch in which switching between ports is achieved by control of ten vanadium dioxide (VO₂) switch junctions, in accordance with various embodiments and implementations of the subject disclosure.

FIGS. 3A, 3B and 3C are representations of three possible states of the example four port switch, in accordance with various embodiments and implementations of the subject disclosure.

FIG. 4 is a three-dimensional (3D) top view representation of an example four port RF switch, in accordance with various embodiments and implementations of the subject disclosure.

FIG. 5A is a three-dimensional top view of a VO₂-based junction and heating element, useable in the example multiport (e.g., four port) switch, in accordance with various embodiments and implementations of the subject disclosure.

FIG. 5B is a 3D three-dimensional top view of an alternative (relative to FIG. 5A) VO₂-based switch junction, useable in an example multiport (e.g., four port) switch, in which the heating element is on top, in accordance with various embodiments and implementations of the subject disclosure.

FIG. 6 is a three-dimensional (3D) top perspective view representation of an example four port RF switch, atop a substrate, coupled to a controller that controls six VO₂-based switches, in accordance with various embodiments and implementations of the subject disclosure.

FIG. 7 is a top view representation showing possible signal paths in the example multiport switch between Port 1 and Port 2, and between Port 3 and Port 4, based on VO₂ switch states, in accordance with various embodiments and implementations of the subject disclosure.

FIG. 8 is a top view representation showing possible signal paths in the example multiport switch between Port 1 and Port 4, and between Port 2 and Port 3, based on VO₂ switch states, in accordance with various embodiments and implementations of the subject disclosure

FIG. 9 is a top view representation showing a signal path in the example multiport switch from Port 1 to Port 3 based on VO₂ switch states, in accordance with various embodiments and implementations of the subject disclosure.

FIG. 10 is a 2D top view representation showing an example of simulated surface current density with two switches (Switch 3 and Switch 4) actuated (in their conductive states), in accordance with various embodiments and implementations of the subject disclosure.

FIG. 11 is a 2D top view representation showing an example of simulated surface current density with four switches (Switch 1, Switch 9, Switch 6 and Switch 8) actuated (in their conductive states), in accordance with various embodiments and implementations of the subject disclosure.

FIG. 12 is a 2D top view representation showing an example layout and example materials of a four port switch, in accordance with various embodiments and implementations of the subject disclosure.

FIGS. 13A and 13B are graphical representations of simulation results showing return loss and insertion loss (FIG. 13A) and isolation (FIG. 13B) versus signal frequency of an example four port RF switch, in accordance with various embodiments and implementations of the subject disclosure.

FIGS. 14A, 14B, 14C, 14D, 14E, 15A, 15B, and 15C are 3D views of an example manufacturing process for a fabricating an example multiport switch, in accordance with various embodiments and implementations of the subject disclosure.

FIGS. 16A, 16B, 16C, 16D, 17A, 17B, and 17C are cross-sectional views of an example manufacturing process for a fabricating an example multiport switch, in accordance with various embodiments and implementations of the subject disclosure.

FIG. 18 is a flow diagram showing example operations related to selectively electrically coupling a first RF port to a second, third or fourth RF port based on controlling metal-insulator transition material switch sets, in accordance with various aspects and implementations of the subject disclosure.

### DETAILED DESCRIPTION

Various factors for RF switches include insertion loss (signal loss through the switch), isolation (preventing signal leakage between paths), and switching speed (how quickly the switch changes states). Existing RF switches often suffer from at least one of high insertion loss, poor isolation, and/or complex fabrication processes, limiting their applicability in space-constrained high-performance scenarios.

Various implementations and embodiments of the technology described herein are generally directed towards a highly efficient, low power, and compact radio frequency (RF) multiport switch that provides reliable switching performance across multiple states while being cost-effective to manufacture. The multiport switch integrates metal-insulator transition (e.g., vanadium dioxide, or VO₂) material, enabling multistate operation for routing an input signal from any available port to any available free port, such as embodied in a four-port switch with distinct states for flexible signal routing across multiple ports.

In one implementation, the transition material-based switch facilitates multiport RF switching using ten series switches designed for reliable RF signal routing, including three distinct operational states. Each switch leverages the phase-transition properties of VO₂, namely between conductive and nonconductive states, to enable controllable, efficient RF switching with very low power requirements. The integration of the ten series switches enhances control over signal flow, allowing for flexible routing and improved isolation between states.

Note that conventional RF switches face limitations in achieving efficient switching with low power consumption while maintaining robustness in challenging environments. Traditional designs often use complex mechanical structures or bulky components, leading to increased costs and limited scalability. In contrast, the technology described herein provides compact RF switches that can provide reliable switching performance across multiple states while being cost-effective to manufacture; the VO₂-based switches meet desirable performance criteria while being straightforward to fabricate on a large scale.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

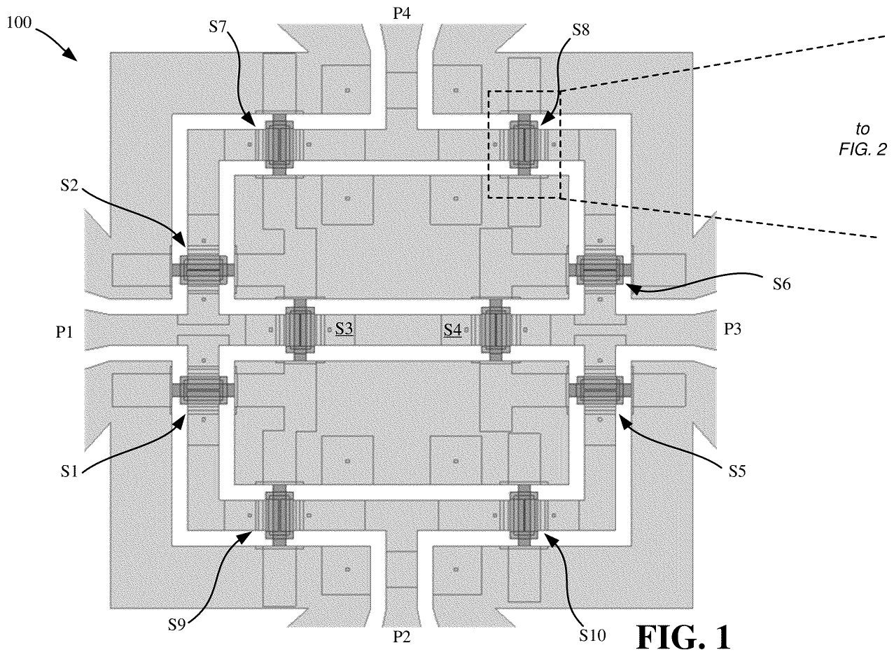

FIG. 1 shows an example top-view of one implementation of a four-port multiport switch (device) 100, including ports P1-P4 and ten switches S1-S10. The device 100 includes ten V+ bias pads (contact terminals) as described herein, and corresponding bias lines for selectively applying voltage (or current) to respective heating elements of a heater network that are associated with the respective switches, to thereby control the conductive or nonconductive states of the VO₂ material as described herein, e.g., one VO₂ material junction per switch.

Note that traditional RF switch designs have predominantly relied on mechanical-based switches, semiconductors, or coaxial relays, each with distinct limitations. Certain technologies provide compactness but suffer from reliability issues and complex fabrication processes. Semiconductor switches offer faster switching but tend to have higher insertion loss and limited isolation. Mechanical relays, while robust, are bulky and costly, limiting their applicability in space-constrained environments.

In contrast, described herein are VO₂-based switches that overcome traditional RF switch limitations. In general, VO₂ material exhibits a temperature-induced phase transition around 67° C. Below this temperature, VO₂ acts as an insulator (high resistivity). As the temperature rises above this threshold, VO₂ transitions into a metallic phase (low resistivity). The insulator-to-metal phase transition in VO₂ occurs at ultrafast speed, on the order of a few femtoseconds (fs). Note that the technology described herein is not limited to any particular phase change material, and, for example, other metal-insulator transition materials such as vanadium trioxide or vanadium pentoxide can be used, as long as the phase can be controllably, reliably, and relatively quickly changed.

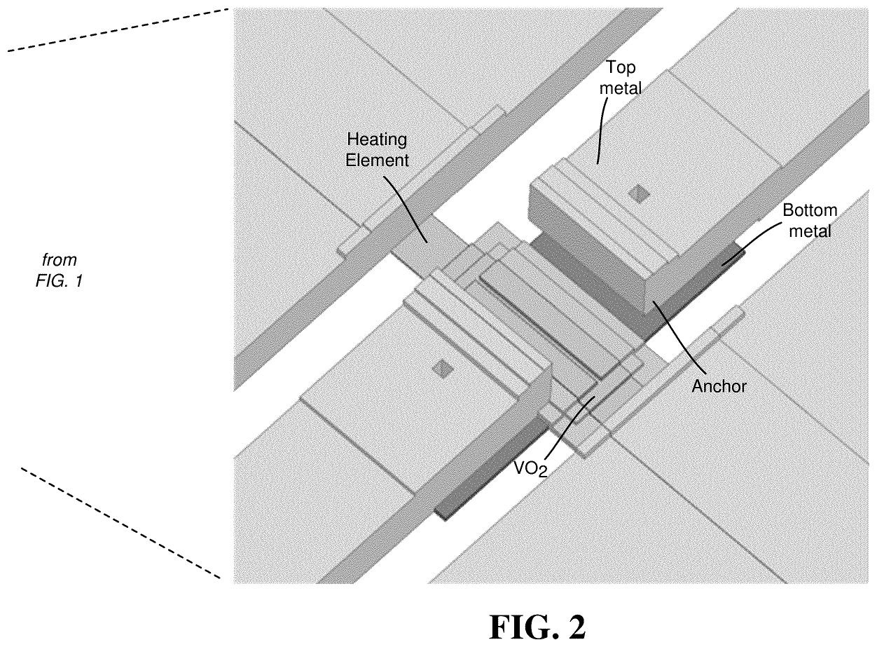

FIG. 2 is a three-dimensional (3D) zoomed-in view of the switch 1 (S1) part of the four-port multiport switch 100 of FIG. 1. A heating element is present to controllably heat the VO₂ material to change the switch junction to its conductive state. In the example embodiment of FIG. 2, the switch is anchored underneath a top metal layer as described herein.

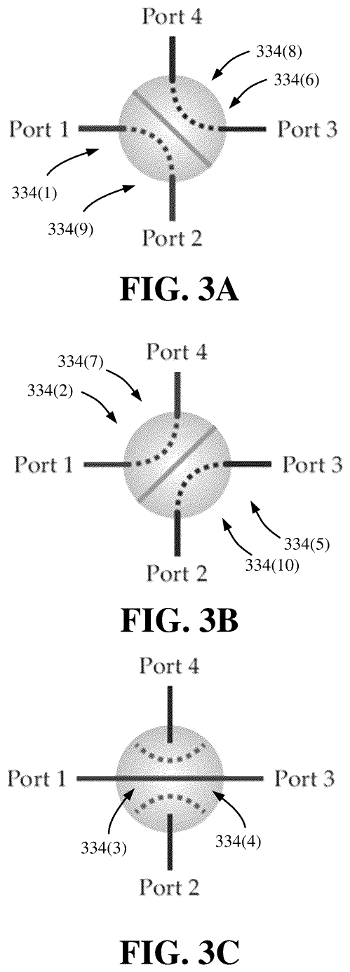

FIGS. 3A-3C show example operational non-blocking connection states, states I-states III, respectively. As can be seen, in FIG. 3A (state I), the conductive or nonconductive state of the switches 334(1) and 334(9) (corresponding to switches S1 and S9, respectively, of FIG. 1) determines whether port P1 is electrically coupled to or decoupled from port P2. Similarly, the conductive or nonconductive state of the switches 334(6) and 334(8) (corresponding to switches S6 and S8, respectively, of FIG. 1) determines whether port P3 is electrically coupled to or decoupled from port P4. Both connections are independent yet can be simultaneous by actuating both the switch pair 334(1) and 334(9), and switch pair 334(6) and 334(8). Note that having two switches per path increase isolation, which is significant with respect to higher RF frequencies.

In FIG. 3B (state II), the conductive or nonconductive state of the switches 334(2) and 334(7) (corresponding to switches S2 and S7, respectively, of FIG. 1) determines whether port P1 is electrically coupled to or decoupled from port P4. Similarly, the conductive or nonconductive state of the switches 334(5) and 334(10) (corresponding to switches S5 and S10, respectively, of FIG. 1) determines whether port P2 is electrically coupled to or decoupled from port P3. Both connections are independent yet can be simultaneous by actuating both the switch pair 334(2) and 334(7), and switch pair 334(7) and 334(10).

In FIG. 3C (state III), the conductive or nonconductive state of the switches 334(3) and 334(4) (corresponding to switches S3 and S4, respectively, of FIG. 1) determines whether port P1 is electrically coupled to or decoupled from port P3. For non-blocking operation, the other switches are in their nonconductive states, although it is feasible to use the device for routing signals from one port to multiple ports.

Thus, an example 4-port switch is designed that includes three operational states I, II and III. The design can route signals between port 1 and 2 and/or port 3 and 4, including at the same time, considered as state I of the device. A signal routed between port 1 to 4 and/or port 2 and 3, which can be routed simultaneously, is considered as state II. A third state, state III, routes signals between port 1 and 3. Note that additional states are feasible by adding more switches. The example implementation shows a symmetrical, ninety-degree RF design so as to offer substantially identical performance regardless of which port is considered as input or output.

The RF performance of the switches is almost similar, as the signal losses usually come from switches and junctions itself. Note that a single path provides somewhat better performance relative to having two paths connected at the same time.

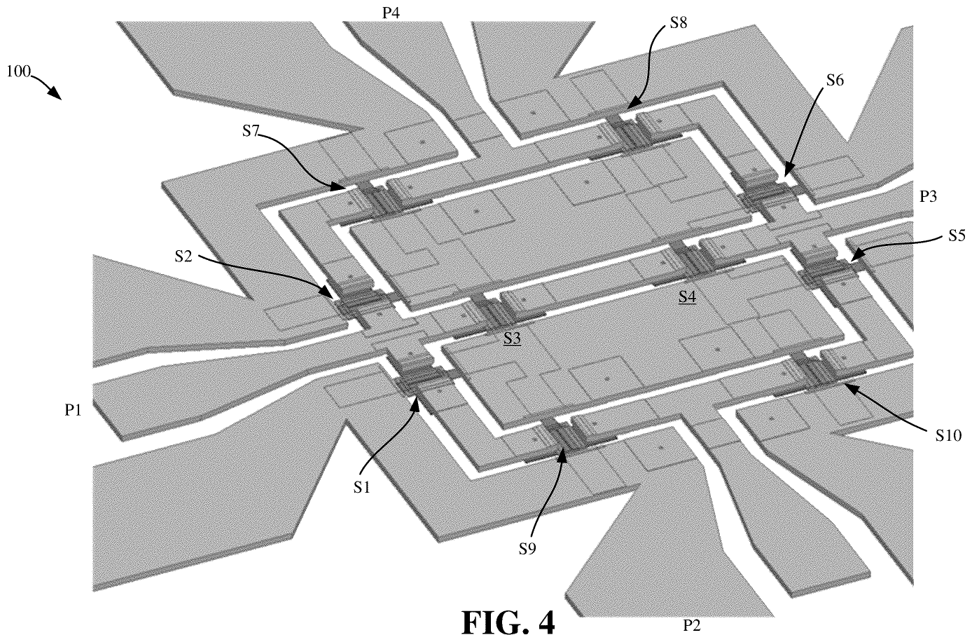

FIG. 4 shows a 3D (partial view) corresponding to the multiport switch device 100 of FIG. 1. The components including the switches S1-S9 and the ports P1-P4 are similarly labeled.

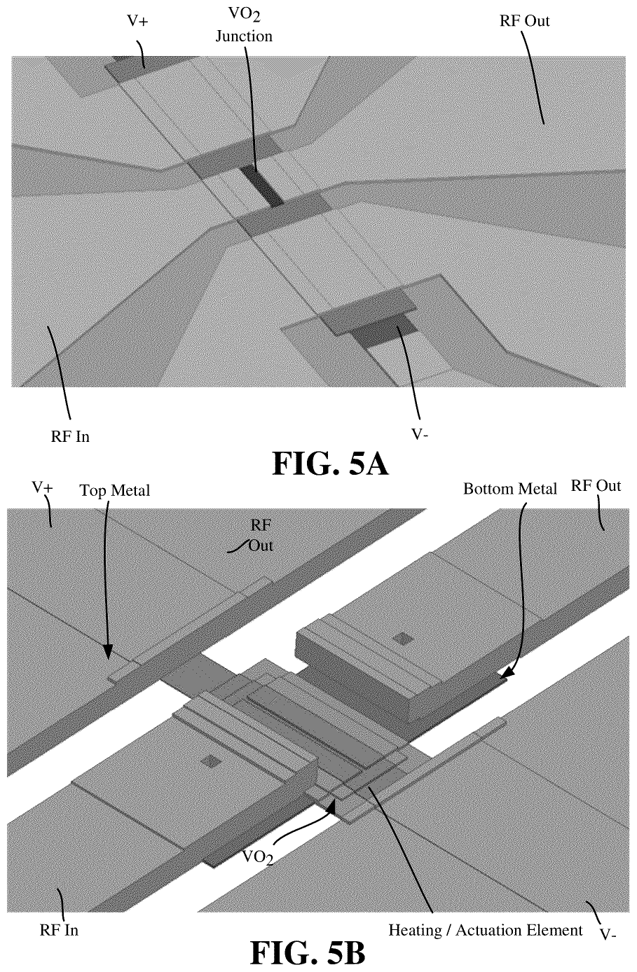

FIGS. 5A and 5B show switch components of an example switch useable in the multiport switch described herein. As can be seen, in FIGS. 5A and 5B, VO₂ material is present in the switch junction, with a heating element that heats up when voltage bias V+ to V− is applied thereto for actuation. The conductors for RF In and RF output ports are also shown, which as can be readily appreciated, only provides a signal path when the VO₂ material is heated above the transition temperature to its conductive state.

Note that while FIG. 5A has similar components to FIG. 5B, in FIG. 5A the heating element is underneath the VO₂ junction. In an alternative to the design of FIG. 5A, in FIG. 5B the heating element is above the VO₂ junction.

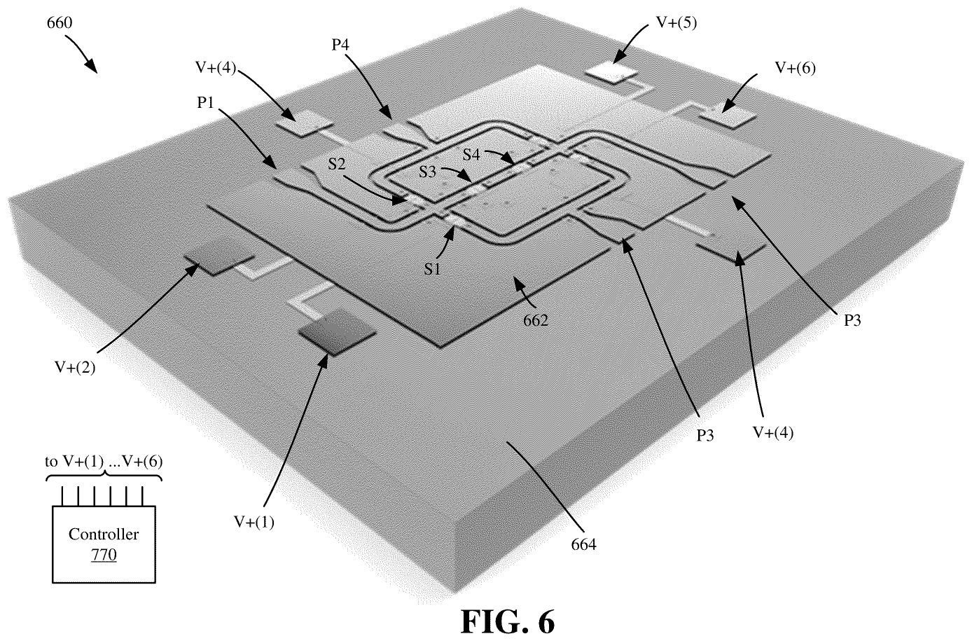

FIG. 6 shows a system 660 that includes a multiport switch device 662 in which the multiport switch is fabricated above a substrate 664. The device 662 is shown as a rendered 3D view. The device 662 includes six voltage pads V+(1)-V+(6); note that in this example, (in contrast to FIG. 4) there are only six switches S1-S6, corresponding to the six voltage (contact) pads V+(1)-V+(6). A controller 770 selectively applies voltage to the voltage pads V+(1)-V+(6) to determine which switches are actuated into their conductive states; although not explicitly shown, it is understood that there are ten such voltage (contact) pads for the ten switches shown in the example of FIG. 4. Also note that the four ports P1-P4 in FIG. 6 are arranged differently relative to the ports in FIG. 4.

It should be noted that six switches as in FIG. 6 (or even five if only one if one switch instead of the switches S3 or S4 is used) can be used to obtain the three states I, II and III of the four port device as described with reference to FIGS. 3A-3C, respectively. However, isolation will not be as good relative to having switch pairs on each signal path, and thus the implementation of FIG. 6 (or one with five switches) suffices for lower frequency applications, but is more limited with respect to usage in higher frequency applications.

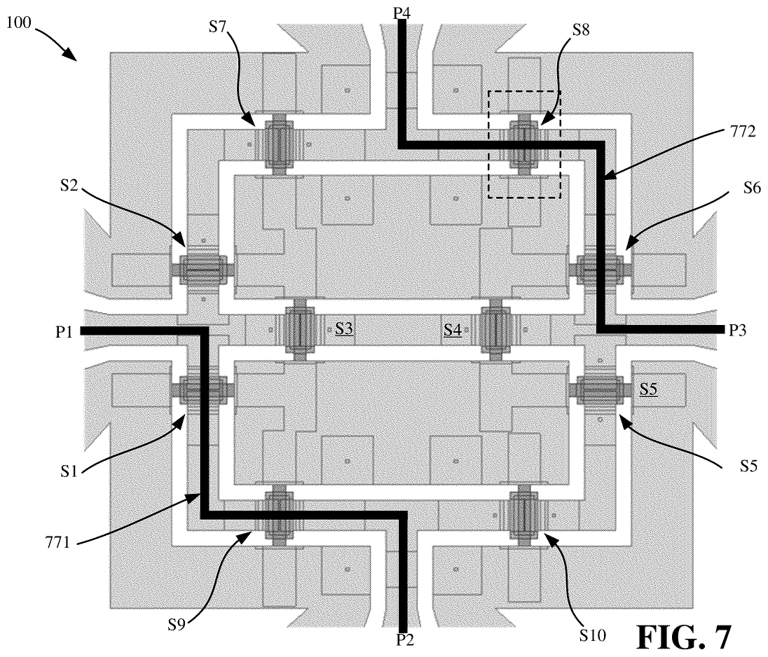

FIG. 7 shows the multiport switch device 100 (with ten switches S1-S10) operating in the first operational state I in which port P1 is coupled to port P2 by actuating switches S1 and S9, providing a first signal path 771 represented by the lower dark line. Switches S2 and S3 are de-actuated to prevent the first RF signals from going beyond them, thereby enhancing isolation. Further, in FIG. 7 port P3 is coupled to port P4 by actuating switches S6 and S8 providing a second signal path 772 represented by the upper dark line. Switches S4 and S5 are de-actuated in this operational state to prevent the first RF signals from going beyond them, thereby enhancing isolation. Note that either of the signal paths 771 or 772 can be individually in use, or both signal paths 771 and 772 can be simultaneously in use.

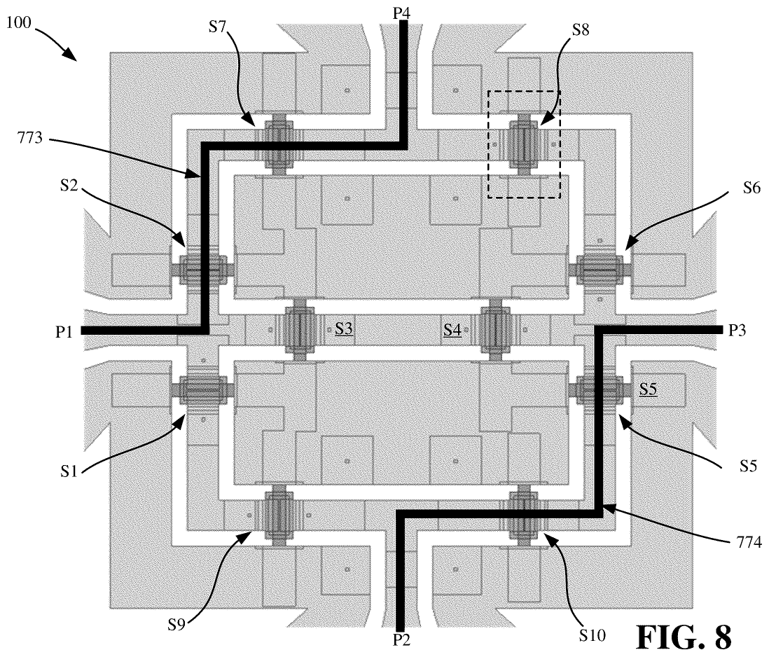

FIG. 8 shows the multiport switch device 100 operating in the second operational state II in which port P1 is coupled to port P4 by actuating switches S2 and S7, providing a third signal path 773 represented by the upper dark line. Switches S1 and S3 are de-actuated to prevent the RF signals from going beyond them, thereby enhancing isolation. Further, in FIG. 7 port P2 is coupled to port P3 by actuating switches S6 and S8 providing a different signal path 774 represented by the lower dark line. Switches S4 and S6 are de-actuated in this operational state to prevent the first RF signals from going beyond them, thereby enhancing isolation. Note that either of the signal paths 773 or 774 can be individually in use, or both signal paths 773 and 774 can be simultaneously in use.

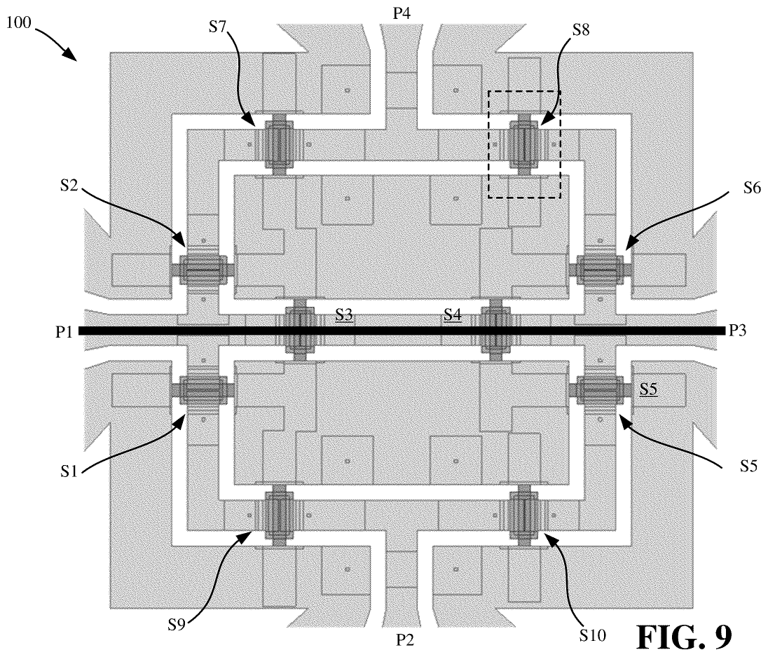

FIG. 9 shows the multiport switch device 100 operating in the third operational state III in which port P1 is coupled to port P3 by actuating switches S3 and S4, providing a fifth signal path 775 represented by the center dark line. Switches S1, S2 and S5-S10 are de-actuated to prevent the RF signals from going beyond them, thereby enhancing isolation.

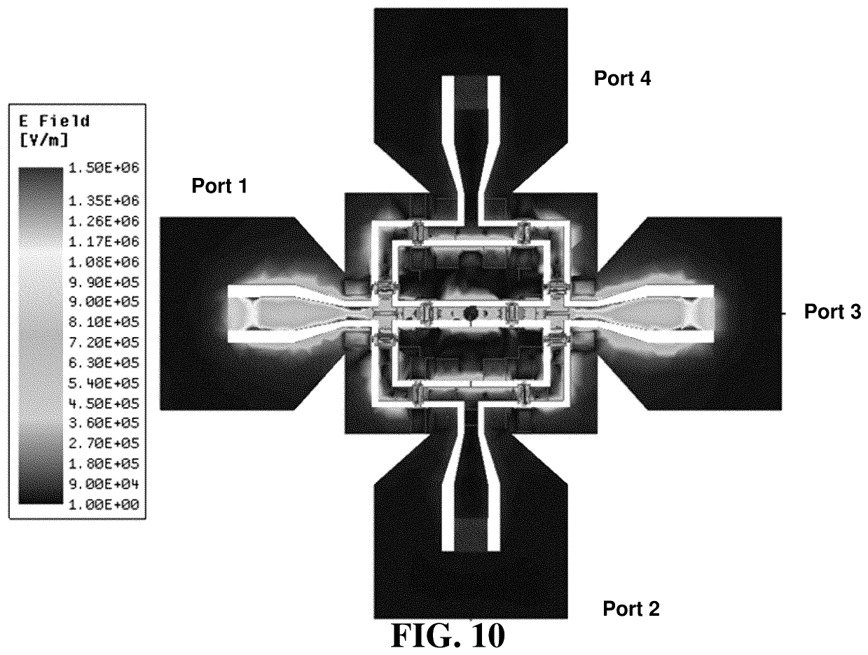

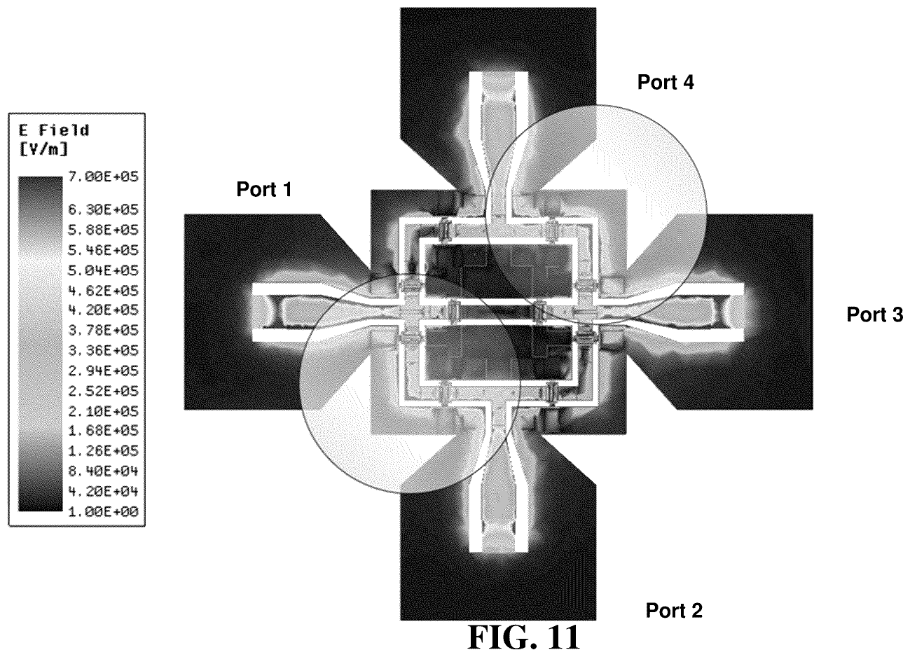

FIG. 10 is a 2D top view representation showing simulated surface current density with one switch pair (Switch 3 and Switch 4) actuated (in their conductive states), along with surface current density E-Field values in volts per meter (V/M). FIG. 11 is a 2D top view representation showing simulated surface current density with two switch pairs (Switch 1 and Switch 9, and Switch 6 and Switch 8) actuated (in their conductive states), along with surface current density E-Field values in volts per meter (V/M).

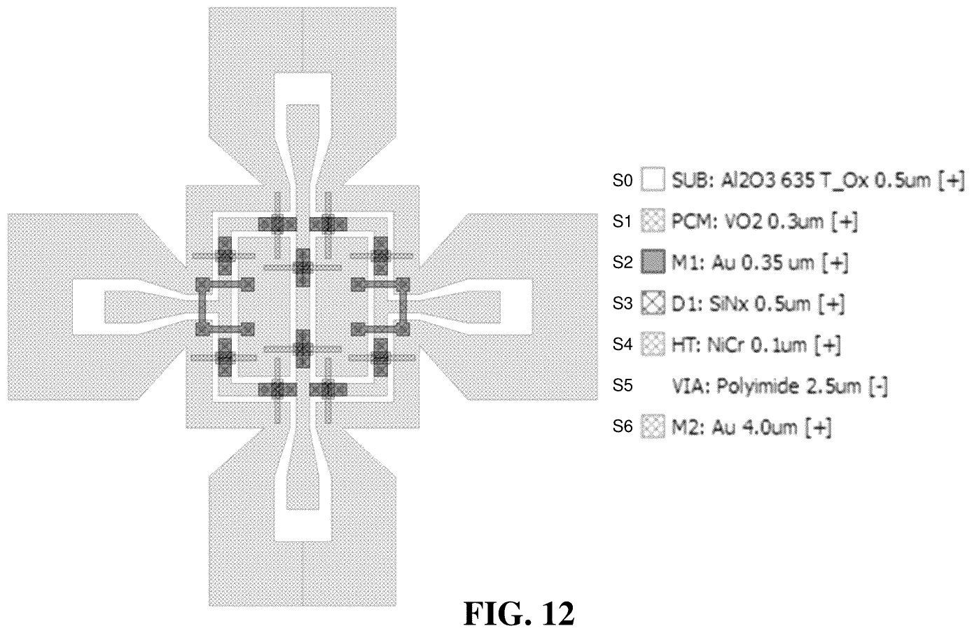

FIG. 12 shows 2D top view representation showing an example layout and example materials of a four port switch. This design is suitable for use in simulations.

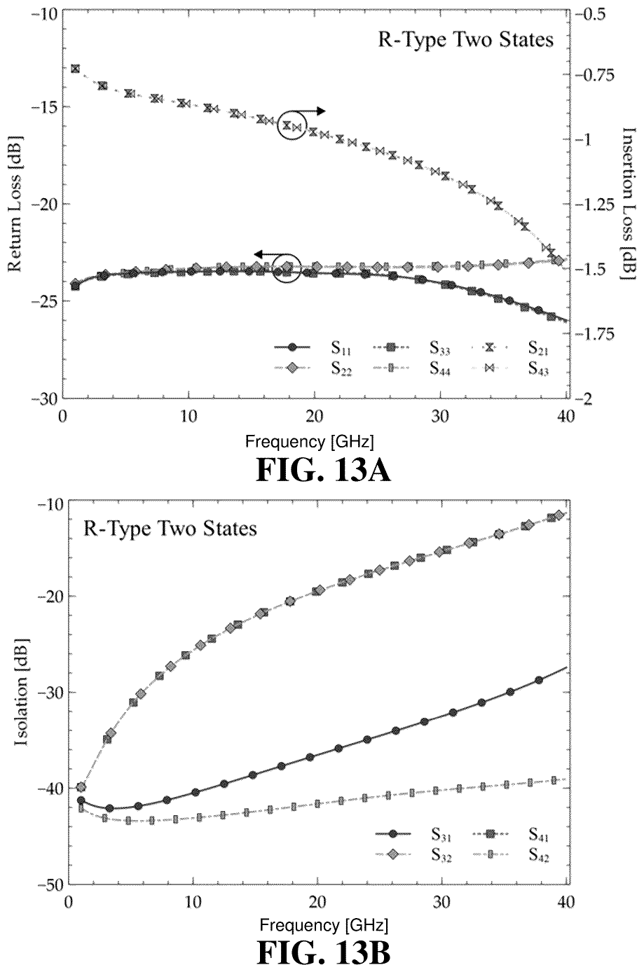

FIG. 13A is a graphical representation of simulation results showing return loss and insertion loss in dB for varying signal frequency. FIG. 13B graphically represents the corresponding isolation.

A detailed manufacturing process has been developed to optimize the production of the example VO₂-based RF multiport switch, facilitating scalability and consistent performance. This example design and process, described herein, is suitable for high-performance RF applications, balancing efficiency, durability, and manufacturability. Note that the materials described with reference to the manufacturing process are nonlimiting examples, and that other suitable materials can be substituted as appropriate for a given application.

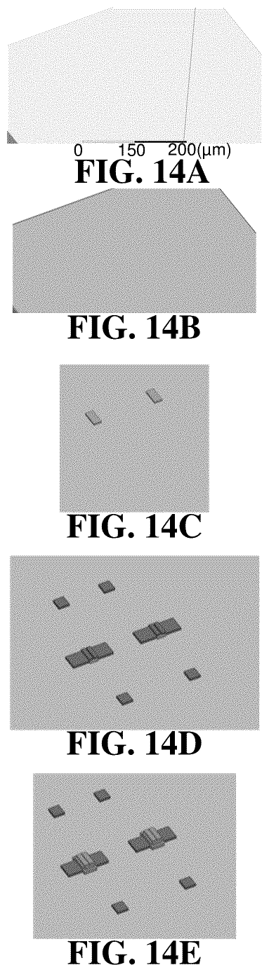

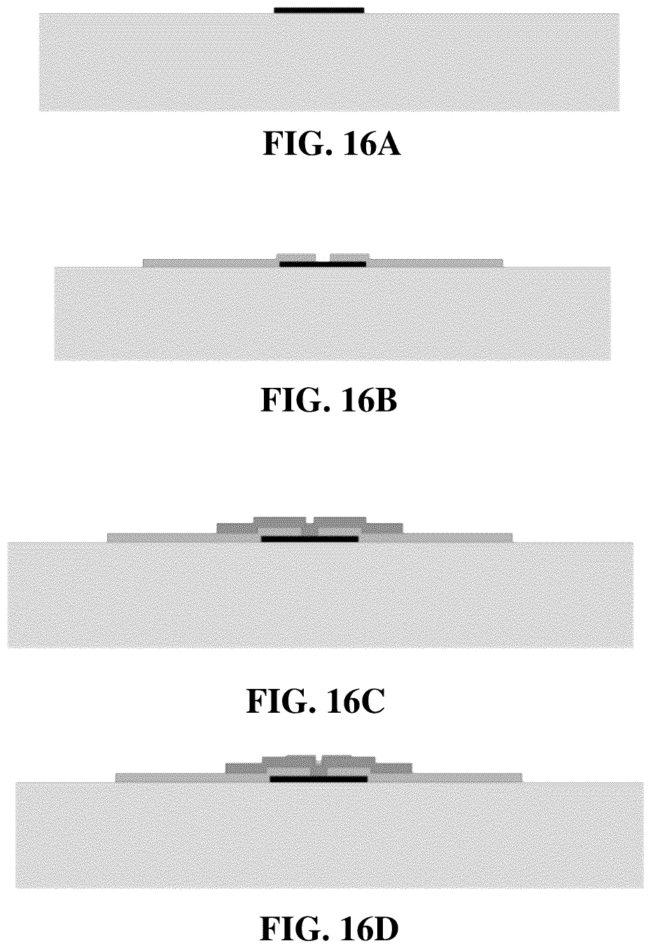

Starting with a substrate (e.g., Al2O3, FIG. 14A, also showing example dimensions in micrometers (μm)) shown in 3D views in FIGS. 14A-14E, at FIG. 14B a first step adds oxide SiNx. A next step (FIG. 14C) deposits the VO₂ phase change material (e.g., 250 nm), which is also represented in the cross-sectional view of FIG. 16A.

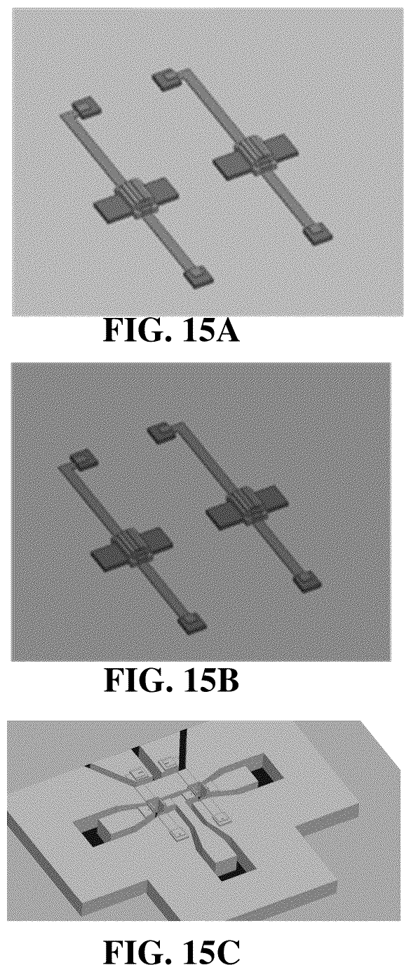

Metal such as gold (Au) (or other suitable metal such as aluminum, copper and so on) is added in a next step, e.g., (added as a mask Cr+Au 100+250 nm), as shown in FIGS. 14D and 16B (cross-sectional view). A Silicon Nitride barrier/mask (e.g., 500 nm Si3N4) is added in a next step, as shown in FIGS. 14D and 16C (cross-sectional view). FIGS. 15A and 16D show adding a heating element, e.g., NiChrome (nickel and chromium), 50 nm.

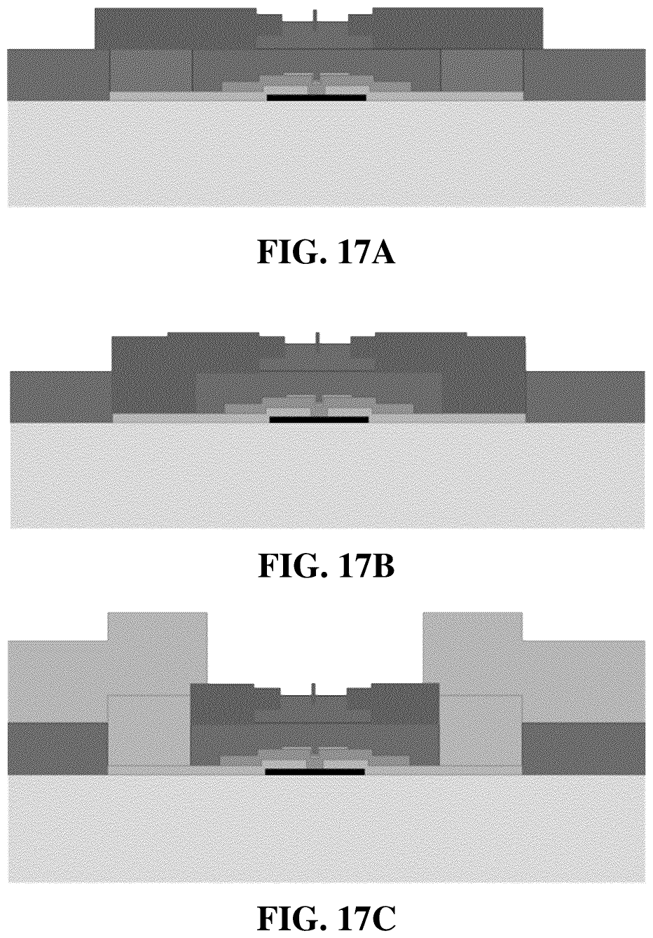

A (e.g., 2.5 μm) mask of polyimide overlays the other materials, as shown in FIGS. 15B and 17A (cross-sectional view). Anchors are added (e.g., metal) as shown in FIG. 17B, and as shown in FIGS. 15C and 17C, electroplated Au (e.g., 4 μm) or other metal is added.

One or more implementations can be embodied in a device. The device can include radio frequency (RF) ports, and an RF multiport switch. The RF multiport switch can include respective selective metal-insulator-transition material switches coupled to the RF ports, and a controllable heater network including respective heating elements that transfer heat to the respective selective metal-insulator-transition material switches. The controllable heater network can be selectively controlled to output heat energy to operate the RF multiport switch in a first operational state in which a first switch of the respective selective metal-insulator-transition material switches is controlled to be to a conductive state that electrically couples a first RF port of the RF ports to a second RF port of the RF ports, a second operational state in which a first switch of the respective selective metal-insulator-transition material switches is controlled to be to a conductive state that electrically couples the first RF port to a third RF port of the RF ports; or a third operational state in which a first switch of the respective selective metal-insulator-transition material switches is controlled to be to a conductive state that electrically couples the first RF port to a fourth RF port of the RF ports.

The first operational state further can electrically couple the third RF port to the fourth RF port.

The first operational state further can electrically decouple the first RF port from the third RF port, and electrically decouple the first RF port from the fourth RF port.

The third operational further can electrically couple the second RF port to the third RF port.

The third operational state further can electrically decouple the second RF port from the first RF port, and electrically decouple the second RF port from the fourth RF port.

The RF multiport switch can include a first metal-insulator-transition material switch, of the respective selective metal-insulator-transition material switches, deployed between the first RF port and the second RF port on a first selectable signal path between the first RF port and the second RF port, a second metal-insulator-transition material switch, of the respective selective metal-insulator-transition material switches, deployed between the first RF port and the fourth RF port on a second selectable signal path between the first RF port and the fourth RF port, a third metal-insulator-transition material switch, of the respective selective metal-insulator-transition material switches, deployed between the first RF port and the third RF port on a third selectable signal path between the first RF port and the third RF port, a fourth metal-insulator-transition material switch, of the respective selective metal-insulator-transition material switches, deployed between the second RF port and the third RF port on a fourth selectable signal path between the second RF port and the third RF port, and a fifth metal-insulator-transition material switch, of the respective selective metal-insulator-transition material switches, deployed between the third RF port and the fourth RF port on a fifth selectable signal path between the third RF port and the fourth RF port.

The RF multiport switch further can include a sixth metal-insulator-transition material switch, of the respective selective metal-insulator-transition material switches, deployed between the first RF port and the third RF port on the third selectable signal path between the first RF port and the third RF port.

The RF multiport switch can include a first metal-insulator-transition material switch of the respective selective metal-insulator-transition material switches, and a ninth metal-insulator-transition material switch of the respective selective metal-insulator-transition material switches, the first metal-insulator-transition material switch and the ninth metal-insulator-transition material switch deployed between the first RF port and the second RF port on a first selectable signal path between the first RF port and the second RF port; a second metal-insulator-transition material switch of the respective selective metal-insulator-transition material switches, and a seventh metal-insulator-transition material switch of the respective selective metal-insulator-transition material switches, the second metal-insulator-transition material switch and the seventh metal-insulator-transition material switch deployed between the first RF port and the fourth RF port on a second selectable signal path between the first RF port and the fourth RF port; a third metal-insulator-transition material switch of the respective selective metal-insulator-transition material switches, and a fourth metal-insulator-transition material switch of the respective selective metal-insulator-transition material switches, the third metal-insulator-transition material switch and the fourth metal-insulator-transition material switch deployed between the first RF port and the third RF port on a third selectable signal path between the first RF port and the third RF port; a fifth metal-insulator-transition material switch of the respective selective metal-insulator-transition material switches, and a tenth metal-insulator-transition material switch of the respective selective metal-insulator-transition material switches, the fifth metal-insulator-transition material switch and the tenth metal-insulator-transition material switch deployed between the second RF port and the third RF port on a fourth selectable signal path between the second RF port and the third RF port; and a sixth metal-insulator-transition material switch of the respective selective metal-insulator-transition material switches, and an eighth metal-insulator-transition material switch of the respective selective metal-insulator-transition material switches, the sixth metal-insulator-transition material switch and the eighth metal-insulator-transition material switch deployed between the third RF port and the fourth RF port on a fifth selectable signal path between the third RF port and the fourth RF port.

The RF ports can be symmetrically distributed relative to a center point of the RF switch matrix.

The RF ports can include a set of four RF ports, a set of eight RF ports, or a set of sixteen RF ports.

Each of the metal-insulator-transition material switches can include at least one of: vanadium trioxide, vanadium dioxide, or vanadium pentoxide.

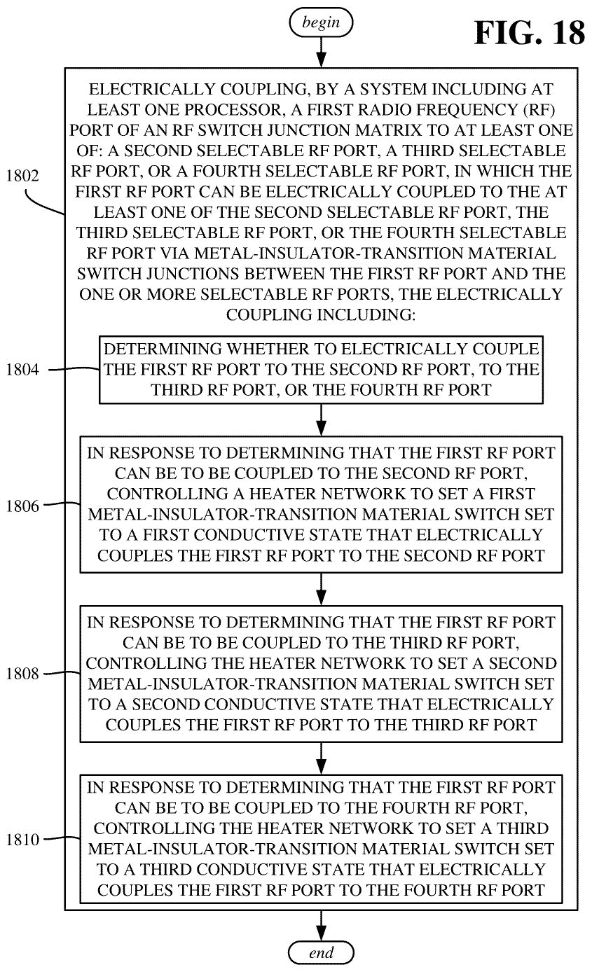

One or more example embodiments, implementations, and/or operations, such as corresponding to example operations of a method, can be represented in FIG. 18. Example operation 1802 represents electrically coupling, by a system comprising at least one processor, a first radio frequency (RF) port of an RF switch junction matrix to at least one of: a second selectable RF port, a third selectable RF port, or a fourth selectable RF port, wherein the first RF port can be electrically coupled to the at least one of the second selectable RF port, the third selectable RF port, or the fourth selectable RF port via metal-insulator-transition material switch junctions between the first RF port and the one or more selectable RF ports, the electrically coupling can include example operations 1804, 1806, 1808 and 1810. Example operation 1804 represents determining whether to electrically couple the first RF port to the second RF port, to the third RF port, or the fourth RF port. Example operation 1806 represents, in response to determining that the first RF port can be to be coupled to the second RF port, controlling a heater network to set a first metal-insulator-transition material switch set to a first conductive state that electrically couples the first RF port to the second RF port. Example operation 1808 represents, in response to determining that the first RF port can be to be coupled to the third RF port, controlling the heater network to set a second metal-insulator-transition material switch set to a second conductive state that electrically couples the first RF port to the third RF port. Example operation 1810 represents, in response to determining that the first RF port can be to be coupled to the fourth RF port, controlling the heater network to set a third metal-insulator-transition material switch set to a third conductive state that electrically couples the first RF port to the fourth RF port.

Controlling the heater network to set the first metal-insulator-transition material switch set to the first conductive state can include controlling a first heating element of the heater network to set a first metal-insulator-transition material switch of the first metal-insulator-transition material switch set to transition the first metal-insulator-transition material switch of the first metal-insulator-transition material switch set to the first conductive state, and controlling a second heating element of the heater network to set a second metal-insulator-transition material switch of the first metal-insulator-transition material switch set to transition the second metal-insulator-transition material switch of the second metal-insulator-transition material switch set to the first conductive state.

The electrically coupling can be a first electrically coupling operation that couples the first RF port to the second RF port, and decouples the first RF port from the third RF port and decouples the first RF port from the fourth RF port, and further operations can include, in a second electrically coupling operation, electrically coupling, by the system, the third RF port to the fourth RF port via controlling the heather network to set a fourth metal-insulator-transition material switch set to a fourth conductive state that electrically couples the third RF port to the fourth RF port.

The electrically coupling can be a first electrically coupling operation that couples the first RF port to the fourth RF port, and decouples the first RF port from the second RF port and decouples the first RF port from the third RF port, and further operations can include, in a second electrically coupling operation, electrically coupling, by the system, the second RF port to the third RF port via controlling the heather network to set a fourth metal-insulator-transition material switch set to a fourth conductive state that electrically couples the second RF port to the third RF port.

The first RF port can be an input port that obtains an input signal, and the electrically coupling can include determining whether the second RF port, the third RF port, or the fourth RF port can be to be an output port usable to obtain the input signal.

The first RF port can be an output port, and further operations can include determining, by the system, whether the second RF port, the third RF port, or the fourth RF port can be an input port useable to obtain an input signal for routing to the first RF port.

One or more implementations can be embodied in a multiport switch. The multiport switch can include a group of radio frequency (RF) ports comprising a first port, a second port, a third port, and a fourth port, and respective metal-insulator-transition material switch pairs corresponding to the group of RF ports. The respective metal-insulator-transition material switch pairs can include a first switch pair comprising a first switch and a ninth switch, a second switch pair comprising a second switch and a seventh switch, a third switch pair comprising a third switch and a fourth switch, a fourth switch pair comprising a fifth switch and a tenth switch, and a fifth switch pair comprising a sixth switch and an eighth switch. The multiport switch can include a controllable heater network including respective heating elements that transfer heat to respective switches of the respective metal-insulator-transition material switch pairs. The controllable heater network can be controlled to output heat via energy to selectively determine respective lower resistance states or respective higher resistance states of the respective metal-insulator-transition material switch pairs. The controllable heater network can be controlled to at least one of: set a first switch pair state to electrically couple the first RF port to the second RF port, set a second switch pair state to electrically couple the first RF port to the fourth RF port, set a third switch pair state to electrically couple the first RF port to the third RF port, set a fourth switch pair state to electrically couple the second RF port to the third RF port, or set a fifth switch pair state to electrically couple the third RF port to the fourth RF port.

The first RF port can be electrically coupled to the second RF port via the first switch pair state being set to a first conductive state, the controllable heater network can be further controlled to electrically decouple the first RF port from the fourth RF port via the second switch pair state being reset to a first nonconductive state, and electrically decouple the first RF port from the third RF port via the third switch pair state being reset to a second nonconductive state, and the third RF port can be electrically coupled to the fourth RF port via the fifth switch pair state being set to a second conductive state.

The first RF port can be electrically coupled to the third RF port via the third switch pair state being set to a conductive state, and the controllable heater network can be further controlled to electrically decouple the first RF port from the second RF port via the first switch pair state being reset to a first nonconductive state, and electrically decouple the first RF port from the fourth RF port via the second switch pair state being reset to a second nonconductive state.

As can be seen, the technology described herein facilitates an ultracompact multiport switch that includes a (e.g., a five, six or ten) series switch configuration based on phase-change alloy/metal-insulator transition material (e.g., VO₂) technology. The inclusion of the series switches offers improved control over signal routing and state isolation, adding flexibility in operational modes. In non-blocking operations, the design provides three distinct operational states, allowing for versatile signal routing with minimal power consumption. The technology described herein also includes an example dedicated manufacturing process, developed to facilitate scalability, ensuring consistent switch performance and enabling cost-effective mass production. The result is a multiport switch with a compact and efficient design for RF applications; by focusing on compactness and operational efficiency, the switch design presents a solution for space-constrained, high-performance RF environments.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
radio frequency (RF) ports; and
an RF multiport switch, comprising:
respective selective metal-insulator-transition material switches coupled to the RF ports, and
a controllable heater network comprising respective heating elements that transfer heat to the respective selective metal-insulator-transition material switches, the controllable heater network being selectively controlled to output heat energy to operate the RF multiport switch in:
a first operational state in which a first switch of the respective selective metal-insulator-transition material switches is controlled to be to a conductive state that electrically couples a first RF port of the RF ports to a second RF port of the RF ports;
a second operational state in which a first switch of the respective selective metal-insulator-transition material switches is controlled to be to a conductive state that electrically couples the first RF port to a third RF port of the RF ports; or
a third operational state in which a first switch of the respective selective metal-insulator-transition material switches is controlled to be to a conductive state that electrically couples the first RF port to a fourth RF port of the RF ports.

2. The device of claim 1, wherein the first operational state further electrically couples the third RF port to the fourth RF port.

3. The device of claim 1, wherein the first operational state further electrically decouples the first RF port from the third RF port, and electrically decouples the first RF port from the fourth RF port.

4. The device of claim 1, wherein the third operational state further electrically couples the second RF port to the third RF port.

5. The device of claim 1, wherein the third operational state further electrically decouples the second RF port from the first RF port, and electrically decouples the second RF port from the fourth RF port.

6. The device of claim 1, wherein the RF multiport switch comprises:
a first metal-insulator-transition material switch, of the respective selective metal-insulator-transition material switches, deployed between the first RF port and the second RF port on a first selectable signal path between the first RF port and the second RF port;
a second metal-insulator-transition material switch, of the respective selective metal-insulator-transition material switches, deployed between the first RF port and the fourth RF port on a second selectable signal path between the first RF port and the fourth RF port;
a third metal-insulator-transition material switch, of the respective selective metal-insulator-transition material switches, deployed between the first RF port and the third RF port on a third selectable signal path between the first RF port and the third RF port;
a fourth metal-insulator-transition material switch, of the respective selective metal-insulator-transition material switches, deployed between the second RF port and the third RF port on a fourth selectable signal path between the second RF port and the third RF port; and
a fifth metal-insulator-transition material switch, of the respective selective metal-insulator-transition material switches, deployed between the third RF port and the fourth RF port on a fifth selectable signal path between the third RF port and the fourth RF port.

7. The device of claim 6, wherein the RF multiport switch further comprises a sixth metal-insulator-transition material switch, of the respective selective metal-insulator-transition material switches, deployed between the first RF port and the third RF port on the third selectable signal path between the first RF port and the third RF port.

8. The device of claim 1, wherein the RF multiport switch comprises:
a first metal-insulator-transition material switch of the respective selective metal-insulator-transition material switches, and a ninth metal-insulator-transition material switch of the respective selective metal-insulator-transition material switches, the first metal-insulator-transition material switch and the ninth metal-insulator-transition material switch deployed between the first RF port and the second RF port on a first selectable signal path between the first RF port and the second RF port;
a second metal-insulator-transition material switch of the respective selective metal-insulator-transition material switches, and a seventh metal-insulator-transition material switch of the respective selective metal-insulator-transition material switches, the second metal-insulator-transition material switch and the seventh metal-insulator-transition material switch deployed between the first RF port and the fourth RF port on a second selectable signal path between the first RF port and the fourth RF port;
a third metal-insulator-transition material switch of the respective selective metal-insulator-transition material switches, and a fourth metal-insulator-transition material switch of the respective selective metal-insulator-transition material switches, the third metal-insulator-transition material switch and the fourth metal-insulator-transition material switch deployed between the first RF port and the third RF port on a third selectable signal path between the first RF port and the third RF port;
a fifth metal-insulator-transition material switch of the respective selective metal-insulator-transition material switches, and a tenth metal-insulator-transition material switch of the respective selective metal-insulator-transition material switches, the fifth metal-insulator-transition material switch and the tenth metal-insulator-transition material switch deployed between the second RF port and the third RF port on a fourth selectable signal path between the second RF port and the third RF port; and
a sixth metal-insulator-transition material switch of the respective selective metal-insulator-transition material switches, and an eighth metal-insulator-transition material switch of the respective selective metal-insulator-transition material switches, the sixth metal-insulator-transition material switch and the eighth metal-insulator-transition material switch deployed between the third RF port and the fourth RF port on a fifth selectable signal path between the third RF port and the fourth RF port.

9. The device of claim 1, wherein the RF ports are symmetrically distributed relative to a center point of the RF multiport switch.

10. The device of claim 1, wherein the RF ports comprise a set of four RF ports, a set of eight RF ports, or a set of sixteen RF ports.

11. The device of claim 1, wherein each of the metal-insulator-transition material switches comprises at least one of: vanadium trioxide, vanadium dioxide, or vanadium pentoxide.

12. A method, comprising:
electrically coupling, by a system comprising at least one processor, a first radio frequency (RF) port of an RF switch junction matrix to at least one of: a second selectable RF port, a third selectable RF port, or a fourth selectable RF port, wherein the first RF port is electrically coupled to the at least one of the second selectable RF port, the third selectable RF port, or the fourth selectable RF port via metal-insulator-transition material switch junctions between the first RF port and the one or more selectable RF ports, the electrically coupling comprising:
determining whether to electrically couple the first RF port to the second RF port, to the third RF port, or the fourth RF port;
in response to determining that the first RF port is to be coupled to the second RF port, controlling a heater network to set a first metal-insulator-transition material switch set to a first conductive state that electrically couples the first RF port to the second RF port;
in response to determining that the first RF port is to be coupled to the third RF port, controlling the heater network to set a second metal-insulator-transition material switch set to a second conductive state that electrically couples the first RF port to the third RF port; and
in response to determining that the first RF port is to be coupled to the fourth RF port, controlling the heater network to set a third metal-insulator-transition material switch set to a third conductive state that electrically couples the first RF port to the fourth RF port.

13. The method of claim 12, wherein the controlling of the heater network to set the first metal-insulator-transition material switch set to the first conductive state comprises controlling a first heating element of the heater network to set a first metal-insulator-transition material switch of the first metal-insulator-transition material switch set to transition the first metal-insulator-transition material switch of the first metal-insulator-transition material switch set to the first conductive state, and controlling a second heating element of the heater network to set a second metal-insulator-transition material switch of the first metal-insulator-transition material switch set to transition the second metal-insulator-transition material switch of the second metal-insulator-transition material switch set to the first conductive state.

14. The method of claim 12, wherein the electrically coupling is a first electrically coupling operation that:
couples the first RF port to the second RF port, and decouples the first RF port from the third RF port and decouples the first RF port from the fourth RF port, and further comprising:
in a second electrically coupling operation, electrically coupling, by the system, the third RF port to the fourth RF port via controlling the heather network to set a fourth metal-insulator-transition material switch set to a fourth conductive state that electrically couples the third RF port to the fourth RF port.

15. The method of claim 12, wherein the electrically coupling is a first electrically coupling operation that:
couples the first RF port to the fourth RF port, and decouples the first RF port from the second RF port and decouples the first RF port from the third RF port, and further comprising:
in a second electrically coupling operation, electrically coupling, by the system, the second RF port to the third RF port via controlling the heather network to set a fourth metal-insulator-transition material switch set to a fourth conductive state that electrically couples the second RF port to the third RF port.

16. The method of claim 12, wherein the first RF port is an input port that obtains an input signal, and wherein the electrically coupling comprises determining whether the second RF port, the third RF port, or the fourth RF port is to be an output port usable to obtain the input signal.

17. The method of claim 12, wherein the first RF port is an output port, and further comprising determining, by the system, whether the second RF port, the third RF port, or the fourth RF port is to be an input port useable to obtain an input signal for routing to the first RF port.

18. A multiport switch, comprising:
a group of radio frequency (RF) ports comprising a first port, a second port, a third port, and a fourth port;
respective metal-insulator-transition material switch pairs corresponding to the group of RF ports, the respective metal-insulator-transition material switch pairs comprising:
a first switch pair comprising a first switch and a ninth switch,
a second switch pair comprising a second switch and a seventh switch,
a third switch pair comprising a third switch and a fourth switch,
a fourth switch pair comprising a fifth switch and a tenth switch, and
a fifth switch pair comprising a sixth switch and an eighth switch;
a controllable heater network comprising respective heating elements that transfer heat to respective switches of the respective metal-insulator-transition material switch pairs, the controllable heater network being controlled to output heat via energy to selectively determine respective lower resistance states or respective higher resistance states of the respective metal-insulator-transition material switch pairs,
wherein the controllable heater network is controlled to at least one of:
set a first switch pair state to electrically couple the first RF port to the second RF port;
set a second switch pair state to electrically couple the first RF port to the fourth RF port;
set a third switch pair state to electrically couple the first RF port to the third RF port;
set a fourth switch pair state to electrically couple the second RF port to the third RF port; or
set a fifth switch pair state to electrically couple the third RF port to the fourth RF port.

19. The multiport switch of claim 18, wherein the first RF port is electrically coupled to the second RF port via the first switch pair state being set to a first conductive state, wherein the controllable heater network is further controlled to electrically decouple the first RF port from the fourth RF port via the second switch pair state being reset to a first nonconductive state, and electrically decouple the first RF port from the third RF port via the third switch pair state being reset to a second nonconductive state, and wherein the third RF port is electrically coupled to the fourth RF port via the fifth switch pair state being set to a second conductive state.

20. The multiport switch of claim 18, wherein the first RF port is electrically coupled to the third RF port via the third switch pair state being set to a conductive state, and wherein the controllable heater network is further controlled to electrically decouple the first RF port from the second RF port via the first switch pair state being reset to a first nonconductive state, and electrically decouple the first RF port from the fourth RF port via the second switch pair state being reset to a second nonconductive state.
